(19) United States
(12) Patent Application Publication
(10) Pub. No.: US 2018/0206330 A1
(43) Pub. Date: Jul. 19, 2018

(54) ELECTROMAGNETIC SHIELDING PROTECTION FILM AND FPC

(71) Applicant: WUHAN CHINA STAR OPTOELECTRONICS TECHNOLOGY CO., LTD., Wuhan City, HB (CN)

(72) Inventors: Hongrui Cao, Wuhan City (CN); Jinjie Zhou, Wuhan City (CN)

(21) Appl. No.: 15/122,409

(22) PCT Filed: Jul. 20, 2016
(86) PCT No.: PCT/CN2016/090578

§ 371 Date: Aug. 30, 2016

(30) Foreign Application Priority Data
Jul. 6, 2016 (CN) 201610527721.7

(51) Int. Cl. H05K 1/02; H05K 9/00; B32B 15/092

(52) U.S. Cl. CPC H05K 1/028; H05K 9/0088; H05K 2201/05; B32B 15/092; B32B 2307/212; H05K 9/0084

(57) ABSTRACT

The present invention provides an electromagnetic shielding protection film and an FPC. The electromagnetic shielding protection film according to the present invention has a simple structure and a reduced thickness and possesses excellent electromagnetic shielding property and is particularly suitable for covering a bending zone of an FPC to ensure an effect of electromagnetic shielding for the bending zone and also to ensure a reduced thickness of the bending zone, providing better flexibility for bending. The FPC according to the present invention includes a bending zone that is covered with the above electromagnetic shielding protection film, which takes the place of a conventionally used electromagnetic shielding composite film that has a relatively large thickness, to ensure an effect of electromagnetic shielding for the bending zone and also to ensure a reduced thickness of the bending zone, providing better flexibility for bending, such that when the FPC of the present invention is used to connect a display module and a main board of a mobile phone, the difficulty of assembling the display module and the main board of the mobile phone can be reduced.

### BACKGROUND OF THE INVENTION

### 1. Field of the Invention

The present invention relates to the field of display technology, and in particular to an electromagnetic shielding protection film and a flexible printed circuit (FPC).

### 2. The Related Arts

A flexible printed circuit (FPC), which is also referred to as a flexible circuit board, is a printed circuit, which is made up of a substrate that is formed of a polyester film or polyimide with wiring formed thereon through etching a copper foil, shows high reliability and excellent flexibility.

Because the FPC is made up of a flexible substrate, it shows various advantages that are not possessed by rigid printed circuit boards, such as being freely bendable, windable, and foldable, allowing for random arrangements to meet space requirements and being allowed to move and stretch in a three-dimensional manner thereby achieving an effect of being integrated with components mounting and wire connection as a unitary structure. The use of FPC helps greatly reduce the overall size of an electronic product, making it applicable to meeting the trends of high density, compactness, and high reliability for the development of electronic products. Thus, FPC has gained wide applications in various fields, including navigation, military, mobile communication, portable computers, computer casing, personal digital assistants (PDAs), and digital cameras.

A general application of the FPC in smart phones is to connect a main board of a mobile phone and a display module for transmission of signals therebetween. An FPC comprises a plurality of zones made up of golden color conductive contact pads, which look like golden fingers, and due to surfaces being coated with gold and being arranged like fingers, they are often referred to as “golden fingers”. Heretofore, the FPC that is used in the phone display screens is generally attached to a top surface of a piece of glass and then folded to the backside of the glass. Thus, the FPC must be provided with at least one flexible and thus bendable area, which will be referred to as a bending zone. As shown in FIG. 1, a conventional FPC generally comprises a bending zone 200 and a golden finger zone 100 and a signal wiring zone 300 respectively located at opposite sides of the bending zone 200. The FPC is connected via the golden finger zone 100 to a display module, and the signal wiring zone 300 of the FPC is connected, via connectors, to a main board of a mobile phone so as to achieve connection between the mobile phone main board and the display module. To prevent interference with signals transmitting with the FPC by electromagnetic interfering signals, it is often to attach an electromagnetic shielding composite film 500 to the signal wiring zone 300 of the FPC to achieve an effect of shielding interference. As shown in FIG. 2, the electromagnetic shielding composite film 500 generally comprises an adhesive bonding layer 510, a polyimide film 520, and an electromagnetic interference shielding film 530 (which will be abbreviated as an “EMI film”) 530, which are stacked in such an order. The adhesive bonding layer 510 has a thickness that is generally 15 micrometers. The polyimide film 520 has a thickness that is generally 12.5 micrometers. The EMI film is a product that is generally commercially available from the market and is generally composed of a conductive resin layer 531, a silver layer 532, and an insulation layer 533 that are stacked in such an order. The EMI film 530 has a thickness that is generally 22 micrometers. Thus, the total thickness of the electromagnetic shielding composite film 500 is 49.5 micrometers. Recently, to achieve a better shielding effect at the bending zone 200 of an FPC, some manufacturers provide an electromagnetic shielding composite film 500 attached to the bending zone 200. However, due to the more severe requirements of the bending zone 200 for rigidity and springing back, and also due to the electromagnetic shielding composite film 500 having a relatively large thickness, the thickness of the bending zone 200 with the electromagnetic shielding composite film 500 attached thereto would be significantly increased and the rigidity and springing back thereof would also become increased, making it adverse to bending. Using such a FPC to connect a display module and a mobile phone main board would increase the difficulty of assembling of the display module and the mobile phone main board.

### SUMMARY OF THE INVENTION

An object of the present invention is to provide an electromagnetic shielding protection film, which has a simple structure, a reduced thickness, and excellent electromagnetic shielding property.

Another object of the present invention is to provide a flexible printed circuit (FPC), which comprises a bending zone that is covered with the above electromagnetic shielding protection film to take the position of the conventionally used electromagnetic shielding composite film that has a great thickness so as to ensure an electromagnetic shielding effect of the bending zone and also ensure a reduced thickness of the bending zone to thereby provide bettered bending performance thereof.

To achieve the above objects, the present invention provides an electromagnetic shielding protection film, which comprises an adhesive bonding layer, a conductive material layer, and an insulation protection layer that are stacked in sequence.

The conductive material layer comprises a metal film or a plurality of uniformly distributed metal particles.

The metal film and the metal particles are formed of a material comprising silver.

The conductive material layer has a thickness of 1 to 15 micrometers; the adhesive bonding layer has a thickness of 1 to 20 micrometers; and the insulation protection layer has a thickness of 2 to 15 micrometers.

The electromagnetic shielding protection film further comprises a first release film attached to a surface of the adhesive bonding layer and a second release film attached to a surface of the insulation protection layer.

The present invention also provides an FPC, which comprises a bending zone and a golden finger zone and a signal wiring zone respectively located at two opposite sides of the bending zone. The bending zone is covered with an electromagnetic shielding protection film. The electromagnetic shielding protection film comprises an adhesive bonding layer, a conductive material layer, and an insulation protection layer that are stacked in sequence. The electromagnetic shielding protection film is attached to the bending zone with the adhesive bonding layer.

The conductive material layer comprises a metal film or a plurality of uniformly distributed metal particles.

The metal film and the metal particles are formed of a material comprising silver.

The conductive material layer has a thickness of 1 to 15 micrometers; the adhesive bonding layer has a thickness of 1 to 20 micrometers; and the insulation protection layer has a thickness of 2 to 15 micrometers.

The signal wiring zone is covered with the electromagnetic shielding protection film or an electromagnetic shielding composite film. The electromagnetic shielding composite film comprises an adhesive bonding layer, a polyimide film, and an electromagnetic shielding film that are stacked in sequence. The electromagnetic shielding film comprises a conductive resin layer, a silver layer, and an insulation layer that are stacked in sequence on the polyimide. The electromagnetic shielding protection film and the electromagnetic shielding composite film are attached to the signal wiring zone with the adhesive bonding layer thereof.

The present invention further provides an electromagnetic shielding protection film, which comprises an adhesive bonding layer, a conductive material layer, and an insulation protection layer that are stacked in sequence, a first release film attached to a surface of the adhesive bonding layer, and a second release film attached to a surface of the insulation protection layer;

wherein the conductive material layer comprises a metal film or a plurality of uniformly distributed metal particles.

The efficacy of the present invention is that the present invention provides an electromagnetic shielding protection film and an FPC. The electromagnetic shielding protection film according to the present invention has a simple structure and a reduced thickness and possesses excellent electromagnetic shielding property and is particularly suitable for covering a bending zone of an FPC to ensure an effect of electromagnetic shielding for the bending zone and also to ensure a reduced thickness of the bending zone, providing better flexibility for bending. The FPC according to the present invention comprises a bending zone that is covered with the above electromagnetic shielding protection film, which takes the place of a conventionally used electromagnetic shielding composite film that has a relatively large thickness, to ensure an effect of electromagnetic shielding for the bending zone and also to ensure a reduced thickness of the bending zone, providing better flexibility for bending, such that when the FPC of the present invention is used to connect a display module and a main board of a mobile phone, the difficulty of assembling the display module and the main board of the mobile phone can be reduced.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as other beneficial advantages, of the present invention will become apparent from the following detailed description of an embodiment of the present invention, with reference to the attached drawings.

In the drawing:

FIG. 1 is a schematic view illustrating the structure of a conventional flexible printed circuit (FPC);

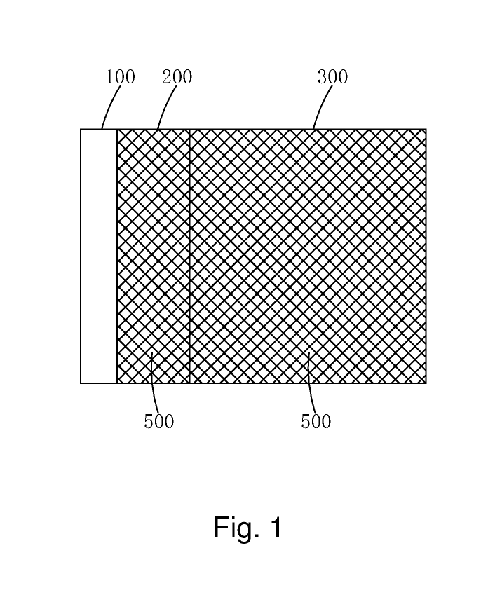

FIG. 2 is a schematic view illustrating the structure of a conventional electromagnetic shielding composite film;

FIG. 3 is a schematic view showing a structure of an electromagnetic shielding protection film according to the present invention;

FIG. 4 is a schematic view showing a structure of an FPC according to a first embodiment of the present invention; and

FIG. 5 is a schematic view showing a structure of an FPC according to a second embodiment of the present invention.

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

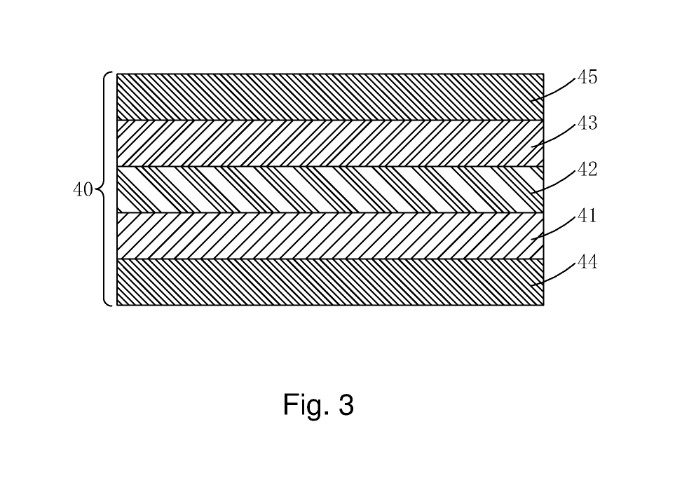

Referring to FIG. 3, the present invention provides an electromagnetic shielding protection film 40, which comprises, stacked in sequence, an adhesive bonding layer 41, a conductive material layer 42, and an insulation protection layer 43.

Specifically, the conductive material layer 42 comprises a metal film or a plurality of uniformly distributed metal particles, and preferably, the metal film and the metal particles are formed of a material comprising silver (Ag). The conductive material layer 42 has a thickness of 1 to 15 micrometers, preferably 5 micrometers.

Specifically, the adhesive bonding layer 41 is formed of a material comprising at least one of epoxy resin, acrylic resin, urethane resin, silicone rubber resin, poly ring xylene resin, bismaleimide resin, and polyimide resin. The adhesive bonding layer 41 has a thickness of 1 to 20 micrometers, preferably 15 micrometers.

Specifically, the insulation protection layer 43 comprises a polyimide film. The insulation protection layer 43 has a thickness of 2 to 15 micrometers, preferably 12.5 micrometers.

Preferably, the electromagnetic shielding protection film 40 further comprises a first release film 44 attached to a surface of the adhesive bonding layer 41. The first release film 44 can be one of a PET (Polyethylene Terephthalate) fluorine-based release film, a PET silicone oil-contained release film, a PET matt release film, and a PE (Polyethylene) release film. The first release film 44 has a thickness of 25 to 100 micrometers. To use the electromagnetic shielding protection film 40, the first release film 44 must be removed first and then, the adhesive bonding layer 41 can be adhesively attached to a surface of an object to which the film is to be attached.

Preferably, the electromagnetic shielding protection film 40 further comprises a second release film 45 attached to a surface of the insulation protection layer 43. The second release film 45 can be one of a PET fluorine-based release film, a PET silicone oil-contained release film, a PET matt release film, and a PE release film. The second release film 45 has a thickness of 25 to 100 micrometers. To use the electromagnetic shielding protection film 40, the second release film 45 must be removed.

Compared to a conventional electromagnetic shielding composite film, the above-described electromagnetic shielding protection film has a simple structure and a reduced thickness and possesses excellent electromagnetic shielding property, making it particularly suitable for covering a bending zone of a flexible printed circuit (FPC) to ensure an effect of electromagnetic shielding for the bending zone and also to ensure a reduced thickness for the bending zone, achieving better property of bending.

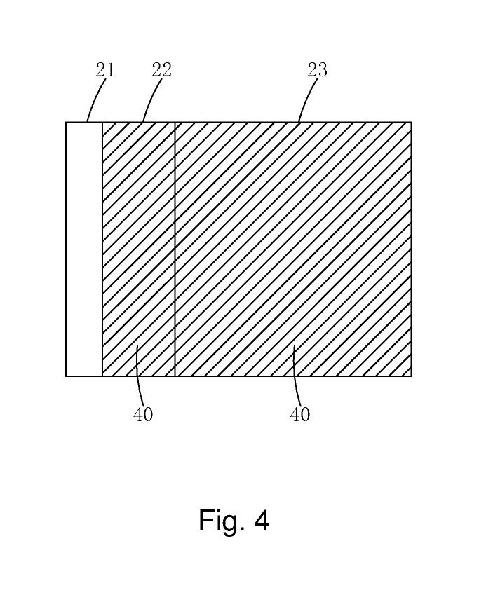

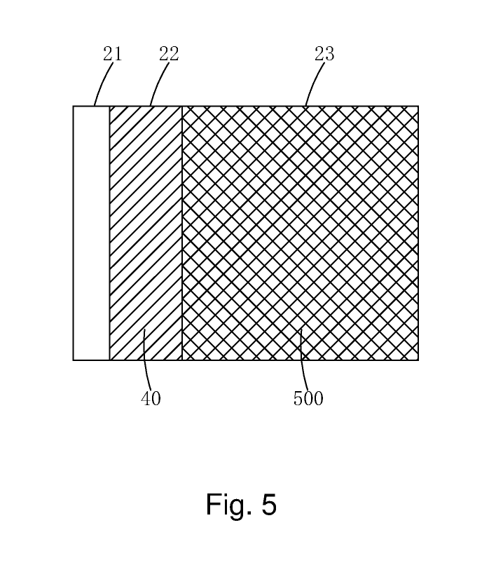

Referring to FIGS. 4 and 5, the present invention also provides an FPC, which comprises a bending zone 22 and a golden finger zone 21 and a signal wiring zone 23 respectively located at two opposite sides of the bending zone 22. The bending zone 22 is covered with an electromagnetic shielding protection film 40. The electromagnetic shielding protection film 40 comprises, stacked in sequence, an adhesive bonding layer 41, a conductive material layer 42, and an insulation protection layer 43. The electromagnetic shielding protection film 40 is attached to the bending zone 22 with the adhesive bonding layer 41.

When the FPC is used in a mobile phone, the golden finger zone 21 is connected to a display module, while the signal wiring zone 23 is connected, via connectors, to a main board of the mobile phone so as to establish connection between the mobile phone main board and the display module by means of the FPC.

Specifically, the conductive material layer 42 comprises a metal film or a plurality of uniformly distributed metal particles, and preferably, the metal film and the metal particles are formed of a material comprising silver. The conductive material layer 42 has a thickness of 1 to 15 micrometers, preferably 5 micrometers.

Specifically, the adhesive bonding layer 41 is formed of a material comprising at least one of epoxy resin, acrylic resin, urethane resin, silicone rubber resin, poly ring xylene resin, bismaleimide resin, and polyimide resin. The adhesive bonding layer 41 has a thickness of 1 to 20 micrometers, preferably 15 micrometers.

Specifically, the insulation protection layer 43 comprises a polyimide film. The insulation protection layer 43 has a thickness of 2 to 15 micrometers, preferably 12.5 micrometers.

Preferably, the electromagnetic shielding protection film 40 further comprises a first release film 44 attached to a surface of the adhesive bonding layer 41. The first release film 44 can be one of a PET fluorine-based release film, a PET silicone oil-contained release film, a PET matt release film, and a PE release film. The first release film 44 has a thickness of 25 to 100 micrometers. To use the electromagnetic shielding protection film 40, the first release film 44 must be removed first and then, the adhesive bonding layer 41 can be adhesively attached to a surface of an object to which the film is to be attached.

Preferably, the electromagnetic shielding protection film 40 further comprises a second release film 45 attached to a surface of the insulation protection layer 43. The second release film 45 can be one of a PET fluorine-based release film, a PET silicone oil-contained release film, a PET matt release film, and a PE release film. The second release film 45 has a thickness of 25 to 100 micrometers. To use the electromagnetic shielding protection film 40, the second release film 45 must be removed.

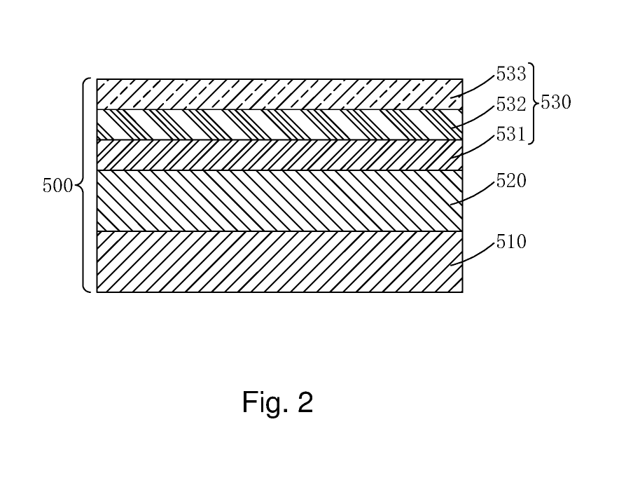

Specifically, the signal wiring zone 23 is covered with an electromagnetic shielding protection film 40 (as shown in FIG. 4) or a known electromagnetic shielding composite film 500 (as shown in FIG. 5). As shown in FIG. 2, the electromagnetic shielding composite film 500 comprises, stacked in sequence, an adhesive bonding layer 510, a polyimide film 520, and an electromagnetic shielding film 530. The electromagnetic shielding film 530 comprises, stacked in sequence on the polyimide film 520, a conductive resin layer 531, a silver layer 532, and an insulation layer 533. Both the electromagnetic shielding protection film 40 and the electromagnetic shielding composite film 500 can be attached to the signal wiring zone 23 by means of the adhesive bonding layer 41/510. Specifically, the insulation layer 533 comprises an organic insulation material.

Specifically, in the electromagnetic shielding composite film 500, the adhesive bonding layer 510 has a thickness of 15 micrometers; the polyimide film 520 has a thickness of 12.5 micrometers; and the electromagnetic shielding film 530 has a thickness of 22 micrometers.

In the above-described FPC, by covering the bending zone 22 with an electromagnetic shielding protection film 40 that has a reduced thickness to take the place of a conventionally used electromagnetic shielding composite film 500 that has a relatively large thickness, it is possible to provide a reduced overall thickness of a bending zone 22, while ensuring an effect of electromagnetic shielding for the bending zone 22, providing better flexibility for bending thereby reducing the difficulty of assembling the display module and the mobile phone main board.

In summary, the present invention provides an electromagnetic shielding protection film and an FPC. The electromagnetic shielding protection film according to the present invention has a simple structure and a reduced thickness and possesses excellent electromagnetic shielding property and is particularly suitable for covering a bending zone of an FPC to ensure an effect of electromagnetic shielding for the bending zone and also to ensure a reduced thickness of the bending zone, providing better flexibility for bending. The FPC according to the present invention comprises a bending zone that is covered with the above electromagnetic shielding protection film, which takes the place of a conventionally used electromagnetic shielding composite film that has a relatively large thickness, to ensure an effect of electromagnetic shielding for the bending zone and also to ensure a reduced thickness of the bending zone, providing better flexibility for bending, such that when the FPC of the present invention is used to connect a display module and a main board of a mobile phone, the difficulty of assembling the display module and the main board of the mobile phone can be reduced.

Based on the description given above, those having ordinary skills of the art may easily contemplate various changes and modifications of the technical solution and technical ideas of the present invention and all these changes and modifications are considered within the protection scope of right for the present invention as defined in the appended claims.

What is claimed is:

1. An electromagnetic shielding protection film, comprising an adhesive bonding layer, a conductive material layer, and an insulation protection layer that are stacked in sequence.

2. The electromagnetic shielding protection film as claimed in claim 1, wherein the conductive material layer comprises a metal film or a plurality of uniformly distributed metal particles.

3. The electromagnetic shielding protection film as claimed in claim 2, wherein the metal film and the metal particles are formed of a material comprising silver.

4. The electromagnetic shielding protection film as claimed in claim 1, wherein the conductive material layer has a thickness of 1 to 15 micrometers; the adhesive bonding layer has a thickness of 1 to 20 micrometers; and the insulation protection layer has a thickness of 2 to 15 micrometers.

5. The electromagnetic shielding protection film as claimed in claim 1 further comprising a first release film attached to a surface of the adhesive bonding layer and a second release film attached to a surface of the insulation protection layer.

6. A flexible printed circuit (FPC), comprising a bending zone and a golden finger zone and a signal wiring zone respectively located at two opposite sides of the bending zone, the bending zone being covered with an electromagnetic shielding protection film, the electromagnetic shielding protection film comprising an adhesive bonding layer, a conductive material layer, and an insulation protection layer that are stacked in sequence, the electromagnetic shielding protection film being attached to the bending zone with the adhesive bonding layer.

7. The FPC as claimed in claim 6, wherein the conductive material layer comprises a metal film or a plurality of uniformly distributed metal particles.

8. The FPC as claimed in claim 7, wherein the metal film and the metal particles are formed of a material comprising silver.

9. The FPC as claimed in claim 6, wherein the conductive material layer has a thickness of 1 to 15 micrometers; the adhesive bonding layer has a thickness of 1 to 20 micrometers; and the insulation protection layer has a thickness of 2 to 15 micrometers.

10. The FPC as claimed in claim 6, wherein the signal wiring zone is covered with the electromagnetic shielding protection film or an electromagnetic shielding composite film, the electromagnetic shielding composite film comprising an adhesive bonding layer, a polyimide film, and an electromagnetic shielding film that are stacked in sequence, the electromagnetic shielding film comprising a conductive resin layer, a silver layer, and an insulation layer that are stacked in sequence on the polyimide, the electromagnetic shielding protection film and the electromagnetic shielding composite film being attached to the signal wiring zone with the adhesive bonding layer thereof.

11. An electromagnetic shielding protection film, comprising an adhesive bonding layer, a conductive material layer, and an insulation protection layer that are stacked in sequence, a first release film attached to a surface of the adhesive bonding layer, and a second release film attached to a surface of the insulation protection layer;
wherein the conductive material layer comprises a metal film or a plurality of uniformly distributed metal particles.

12. The electromagnetic shielding protection film as claimed in claim 11, wherein the metal film and the metal particles are formed of a material comprising silver.

13. The electromagnetic shielding protection film as claimed in claim 11, wherein the conductive material layer has a thickness of 1 to 15 micrometers; the adhesive bonding layer has a thickness of 1 to 20 micrometers; and the insulation protection layer has a thickness of 2 to 15 micrometers.
